(19) United States
(12) Patent Application Publication
(10) Pub. No.: US 2024/0411942 A1
(43) Pub. Date: Dec. 12, 2024

(54) INTERACTIVE GENERATIVE DESIGN WITH SENSITIVITY ANALYSIS AND PROBABILITY VISUALIZATION FOR CATEGORICAL DESIGN VARIABLES

(71) Applicant: AUTODESK, INC., San Francisco, CA (US)

(72) Inventors: Mehran EBRAHIMI, Toronto (CA); Hyunmin CHEONG, Toronto (CA); Pradeep Kumar JAYARAMAN, Toronto (CA)

(21) Appl. No.: 18/414,322

(22) Filed: Jan. 16, 2024

Related U.S. Application Data
(60) Provisional application No. 63/507,073, filed on Jun. 8, 2023.

(51) Int. Cl. G06F 30/12

(52) U.S. Cl. CPC G06F 30/12

(57) ABSTRACT

Techniques for interactive generative design with sensitivity analysis and probability visualization for categorical design variables include a computer-implemented method for evaluating an impact of categorical design variables on a design problem solution comprises receiving information regarding choices for one or more categorical design variables associated with each of a plurality of design members of a design problem, determining a respective sensitivity of an objective function to the choices for the one or more categorical design variables for each design member of the plurality of design members, determining a respective visual aspect for each design member based on the respective sensitivity, displaying, on a user interface, a graphical depiction of the plurality of design members, wherein each design member is displayed using the respective visual aspect, and displaying, on the user interface, a key for interpreting the respective visual aspects.

### CROSS-REFERENCE TO RELATED APPLICATIONS

This application claims benefit of the United States Provisional patent application titled “TECHNIQUES FOR OPTIMIZED GENERATIVE DESIGN,” filed Jun. 8, 2023, and having Ser. No. 63/507,073. The subject matter of this related application is hereby incorporated herein by reference.

### BACKGROUND

### Field of the Various Embodiments

The various embodiments relate generally to generative design and design optimization, more specifically, to Interactive Generative Design with Sensitivity Analysis and Probability Visualization for Categorical Design Variables.

### Description of the Related Art

Generative design is an iterative design process that creates outputs with specified constraints to varying degrees. Designers or engineers input design goals into the generative design software, along with parameters such as performance or spatial requirements, materials, manufacturing methods, and cost constraints. In a typical generative design or design optimization software, the algorithm solves the optimization problem by maximizing or minimizing a target mathematical equation called objective function while satisfying one or more constraint functions and outputs a single solution or a set of solutions found. One well-known limitation of this type of computer-user interaction is that the solutions themselves do not help the user understand the characteristics of the design space and how such solutions were generated. This issue becomes more pronounced when the design variables are categorical choices, e.g., choosing one material type over another. Simply outputting the optimal choice found by the algorithm does not facilitate the user to understand why that choice was made. Categorical design variables are inherently discontinuous, and their values belong to an unordered set of available choices while continuous design variables are free to take any value within their bounds. Examples of such variables in frame structures include beam cross-section outlines and materials. In real-world applications, only a limited number of cross-sectional profiles and material choices may be available to design a structure due to various limitations such as manufacturing process and cost.

Existing optimization techniques applied to structural problems with categorical variables can be classified into gradient-free and gradient-based schemes. Most methods developed for these problems utilize gradient-free optimizers such as the branch-and-bound, genetic algorithm (GA), simulated annealing and particle swarm optimization, among others. It is well-known that due to the combinatorial nature of problems with categorical design variables, the computational cost associated with exploring their design space, which typically grows exponentially with the number of variables, becomes too complex for large-scale problems using the gradient-free optimization routines. Employing gradient-based optimization techniques can be considered as a remedy to lessen the scalability issue. However, as the categorical variables are discontinuous and more importantly unordered, computing the gradients of objective and constraint functions with respect to these variables is problematic.

Previous solutions in this area apply some form of approximation to compute the objective function gradients by converting the categorical variables to continuous variables, which only makes sense if the variables are ordered. These methods also used rounding techniques to enforce the discontinuity of the categorical variables. One other solution is to work with the attributes of categorical variables. For example, instead of operating directly on the cross-sectional outlines, their areas can be taken as design variables. However, this becomes troublesome when categorical variables have multiple attributes influencing the optimization progress in a conflicting manner.

As the forgoing illustrates, what is needed in the art are techniques to calculate gradients of objective functions with respect to categorical variables and techniques to inform the user about the categorical design variables during the optimization process.

### SUMMARY

Various embodiments of the present disclosure set forth a computer-implemented method for evaluating an impact of categorical design variables on a design problem solution comprises receiving information regarding choices for one or more categorical design variables associated with each of a plurality of design members of a design problem, determining a respective sensitivity of an objective function to the choices for the one or more categorical design variables for each design member of the plurality of design members, determining a respective visual aspect for each design member based on the respective sensitivity, displaying, on a user interface, a graphical depiction of the plurality of design members, wherein each design member is displayed using the respective visual aspect, and displaying, on the user interface, a key for interpreting the respective visual aspects.

Other embodiments include, without limitation, one or more computer readable media including instructions for performing one or more aspects of the disclosed techniques and a system that implements one or more aspects of the disclosed techniques.

At least one technical advantage of the disclosed techniques relative to the prior art is that, with the disclosed techniques, gradient-based optimization techniques to be used for design problems with both continuous design variables and categorical design variables. The disclosed techniques further provide improved ways to view the impact and relevance of different categorical design variable choices on a design problem. The disclosed techniques enable the user to quickly compare different choices for the same categorical design variable and the impact of those choices on a design solution without having to compare and contrast many different design solutions to infer the impact of the choices. As a result, the overall design process can be completed faster. In addition, the disclosed techniques are more computationally efficient than prior art techniques and use fewer computing resources. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a system configured to implement one or more aspects of the present disclosure;

FIG. 2 is a block diagram of a computing device according to various embodiments;

FIG. 3 shows an example of a design problem with categorical design variables according to various embodiments;

FIG. 4 shows another example of a design problem with categorical design variables according to various embodiments;

FIG. 5 shows an example of a user interface for visualizing the design problem of FIG. 4 according to various embodiments;

FIG. 6 shows another example of the user interface for visualizing the design problem of FIG. 4 according to various embodiments;

FIG. 7 shows another example of the user interface for visualizing the design problem of FIG. 4 according to various embodiments;

FIG. 8 shows another example of the user interface for visualizing the design problem of FIG. 4 according to various embodiments;

FIG. 9 sets forth a flow diagram of method steps for optimizing a design problem with categorical design variables, according to various embodiments; and

FIG. 10 sets forth a flow diagram of method steps for visualizing design problem with categorical design variables, according to various embodiments,

FIG. 11 sets forth a flow diagram of method steps for bi-level optimization of a design problem with categorical design variables, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

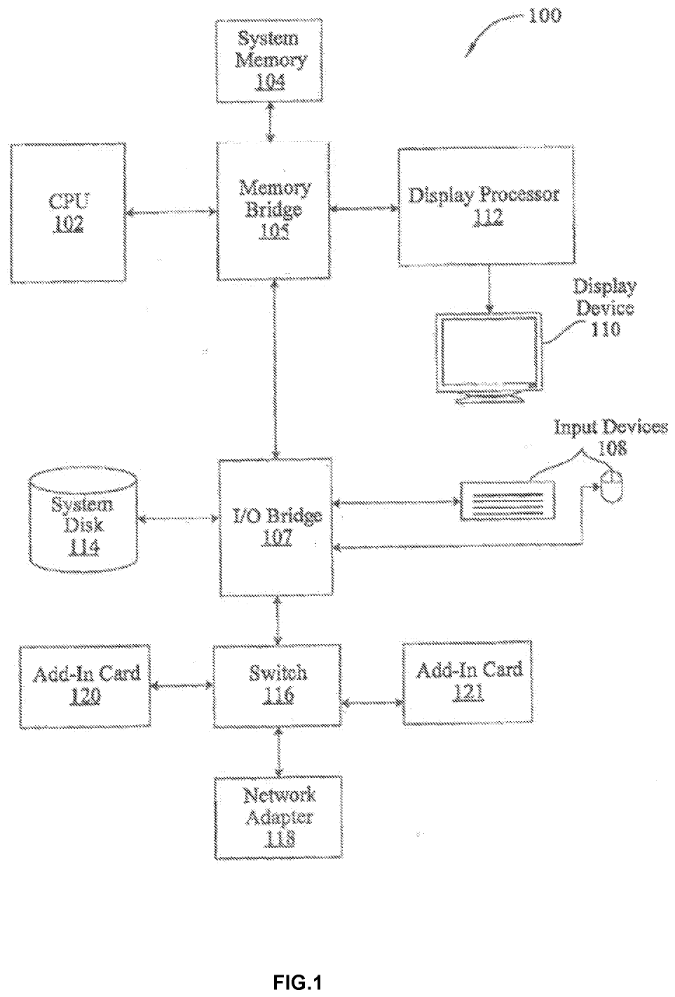

FIG. 1 is a block diagram of a system configured to implement one or more aspects of the present disclosure. This figure in no way limits or is intended to limit the scope of the present disclosure. In various implementations, system 100 may be an augmented reality, virtual reality, or mixed reality system or device, a personal computer, video game console, personal digital assistant, mobile phone, mobile device or any other device suitable for practicing one or more embodiments of the present disclosure. Further, in various embodiments, any combination of two or more systems 100 may be coupled together to practice one or more aspects of the present disclosure.

As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e . . . , a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, one or more of the various graphical user interfaces are displayed to one or more users via display device 110, and the one or more users can input data into and receive visual output from those various graphical user interfaces.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121.

Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114.

Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 incorporates circuitry optimized for graphics and video processing, including, for example, video output circuitry, and constitutes a graphics processing unit (GPU). In another embodiment, display processor 112 incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments of the present disclosure, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured to process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 100 may be a robot or robotic device and may include CPU 102 and/or other processing units or devices and system memory 104. In such embodiments, system 100 may or may not include other elements shown in FIG. 1. System memory 104 and/or other memory units or devices in system 100 may include instructions that, when executed, cause the robot or robotic device represented by system 100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

FIG. 1 is a block diagram of a computer system 100 configured to implement one or more aspects of the present invention. As shown, computer system 100 includes, without limitation, a central processing unit (CPU) 102 and a system memory 104 coupled to a parallel processing subsystem 112 via a memory bridge 105 and a communication path 113. Memory bridge 105 is further coupled to an I/O (input/output) bridge 107 via a communication path 106, and I/O bridge 107 is, in turn, coupled to a switch 116. As persons skilled in the art will appreciate, computer system 100 can be any type of technically feasible computer system, including, without limitation, a server machine, a server platform, a desktop machine, laptop machine, or a hand-held/mobile device.

In operation, I/O bridge 107 is configured to receive user input information from input devices 108, such as a keyboard or a mouse, and forward the input information to CPU 102 for processing via communication path 106 and memory bridge 105. Switch 116 is configured to provide connections between I/O bridge 107 and other components of the computer system 100, such as a network adapter 118 and various add-in cards 120 and 121.

As also shown, I/O bridge 107 is coupled to a system disk 114 that can be configured to store content and applications and data for use by CPU 102 and parallel processing subsystem 112. As a general matter, system disk 114 provides non-volatile storage for applications and data and can include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and the like, can be connected to I/O bridge 107 as well.

In various embodiments, memory bridge 105 can be a Northbridge chip, and I/O bridge 107 can be a Southbridge chip. In addition, communication paths 106 and 113, as well as other communication paths within computer system 100, can be implemented using any technically suitable protocols, including, without limitation, AGP (Accelerated Graphics Port), HyperTransport, or any other bus or point-to-point communication protocol known in the art.

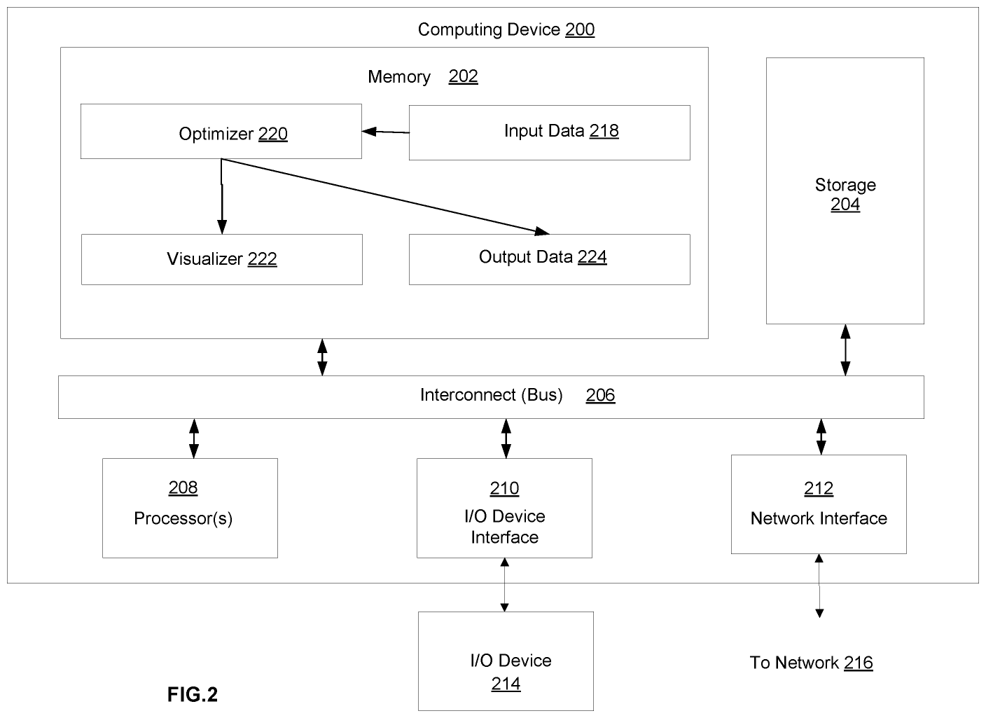

In some embodiments, parallel processing subsystem 112 comprises a graphics subsystem that delivers pixels to a display device 110 that can be any conventional cathode ray tube, liquid crystal display, light-emitting diode display, or the like. In such embodiments, the parallel processing subsystem 112 incorporates circuitry optimized for graphics and video processing, including, for example, video output circuitry. As described in greater detail below in FIG. 2, such circuitry can be incorporated across one or more parallel processing units (PPUs) included within parallel processing subsystem 112. In other embodiments, the parallel processing subsystem 112 incorporates circuitry optimized for general purpose and/or compute processing. Again, such circuitry can be incorporated across one or more PPUs included within parallel processing subsystem 112 that are configured to perform such general purpose and/or compute operations. In yet other embodiments, the one or more PPUs included within parallel processing subsystem 112 can be configured to perform graphics processing, general purpose processing, and compute processing operations. System memory 104 includes at least one device driver 103 configured to manage the processing operations of the one or more PPUs within parallel processing subsystem 112.

In various embodiments, parallel processing subsystem 112 can be integrated with one or more other elements of FIG. 1 to form a single system. For example, parallel processing subsystem 112 can be integrated with CPU 102 and other connection circuitry on a single chip to form a system on chip (SoC).

It will be appreciated that the system shown herein is illustrative and that variations and modifications are possible. The connection topology, including the number and arrangement of bridges, the number of CPUs 102, and the number of parallel processing subsystems 112, can be modified as desired. For example, in some embodiments, system memory 104 could be connected to CPU 102 directly rather than through memory bridge 105, and other devices would communicate with system memory 104 via memory bridge 105 and CPU 102. In other alternative topologies, parallel processing subsystem 112 can be connected to I/O bridge 107 or directly to CPU 102, rather than to memory bridge 105. In still other embodiments, I/O bridge 107 and memory bridge 105 can be integrated into a single chip instead of existing as one or more discrete devices. Lastly, in certain embodiments, one or more components shown in FIG. 1 may not be present. For example, switch 116 could be eliminated, and network adapter 118 and add-in cards 120, 121 would connect directly to I/O bridge 107.

FIG. 2 is a block diagram of a computing device according to various embodiments. As shown, computing device 200 includes, without limitation, memory 202, a storage 204, an interconnect (bus) 206, one or more processor(s) 208, an input/output (I/O) device interface 210, and a network interface 212. Memory 202 includes, without limitation, input data 218, optimizer 220, visualizer 222, and output data 224. As further shown, computing device 200 is coupled, without limitation, to I/O devices 214 and a network 216.

Computing device 200 could be a desktop computer, a laptop computer, a smart phone, a personal digital assistant (PDA), tablet computer, a remote server, or any other type of computing device configured to receive input, process data, and optionally display images, and is suitable for practicing one or more embodiments. In some embodiments, computing device 200 corresponds to computer system 100 in FIG. 1. Computing device 200 described herein is illustrative and any other technically feasible configurations fall within the scope of the present disclosure.

Processor(s) 208 includes any suitable processor implemented as a central processing unit (CPU), a graphics processing unit (GPU), an application-specific integrated circuit (ASIC), a field programmable gate array (FPGA), an artificial intelligence (AI) accelerator, a multi-core processor, any other type of processor, or a combination of two or more processors of a same or different types. For example, processor(s) 208 could include a CPU and a GPU configured to operate in conjunction with each other. In general, processor(s) 208 can be any technically feasible hardware unit capable of processing data and/or executing software applications. Further, in the context of this disclosure, the computing elements shown in computing device 200 can correspond to a physical computing system (e.g., a system in a data center) or can be a virtual computing instance executing within a computing cloud.

I/O device interface 210 enables communication of I/O devices 214 with processor(s) 208. I/O device interface 210 generally includes the logic for interpreting addresses corresponding to I/O devices 214 that are generated by processor(s) 208. I/O device interface 210 can also be configured to implement handshaking between processor(s) 208 and I/O devices 214, and/or generate interrupts associated with I/O devices 214. I/O device interface 210 can be implemented as any technically feasible interface circuit or system.

In some embodiments, I/O devices 214 include devices capable of providing input, such as a keyboard, a mouse, a touch-sensitive screen, and so forth, as well as devices capable of providing output, such as a display device. Additionally, I/O devices 214 can include devices capable of both receiving input and providing output, such as a touchscreen, a universal serial bus (USB) port, and so forth. I/O devices 214 can be configured to receive various types of input from an end-user (e.g., a designer) of computing device 200, and to also provide various types of output to the end-user of computing device 200, such as displayed digital images or digital videos or text.

Network interface 212 serves as the interface between the computer and the network 216. Network interface 212 facilitates the transmission and reception of data. Network interface 212 includes, without limitation, hardware, software, or a combination of hardware and software. In some embodiments, network interface 212 supports one or more communication protocols, such as Ethernet, Wi-Fi, Bluetooth, among others.

In some embodiments network 216 includes any technically feasible type of communications network that allows data to be exchanged between computing device 200 via network interface 212 and external entities or devices, such as a web server or another networked computing device. For example, network 216 can include a wide area network (WAN), a local area network (LAN), a wireless (WiFi) network, and/or the Internet, among others.

Memory 202 includes a random access memory (RAM) module, a flash memory unit, or any other type of memory unit or combination thereof. Processor(s) 208, I/O device interface 210, and network interface 212 are configured to read data from and write data to memory 202. Memory 202 includes various software programs that can be executed by processor(s) 208 and application data associated with the software programs, such as input data 218, optimizer 220, visualizer 222 and output data 224. Optimizer 220 solves a design problem having both continuous design variables and categorical design variables based on one or more evaluation criteria. Depending upon the design problem, the optimizer considers the governing physics and/or system equations as well as any imposed constraints on solutions to the design problem. In each step of optimization, visualizer 222 displays sensitivities and probabilities of each design variable within the solution. Optimizer 220 then saves the design results as output data 224.

Input data 218 includes, without limitation, an objective function J, one or more constraint functions g, continuous design variables x and bounds for the continuous design variables x, categorical variables c and available choices for the categorical variables c, and a temperature parameter for a simulated annealing process that controls exploration and exploitation capabilities while solving the design problem. Optimizer 220 performs the optimization process after receiving input data 218. Optimizer 220 optimizes objective function J in Equation 1.

$$\\ \begin{matrix}{min}_{x , c} {}_{} J ( u ( x , c ) , x , c ) subject to R ( u ( x , c ) , x , c ) = 0 & Equation 1\end{matrix}$$

$$\\ g ( u ( x , c ) , x , c ) \leq 0 , {lb}_{i} \leq {x}_{i} \leq {ub}_{i} , i = 1 , … , {n}_{x} ,$$

$$\\ {c}_{i} ∈ \{ 1 , … , {N}_{i} \} , i = 1 , … , {n}_{c} .$$

In Equation, J is the scalar-valued objective function, g∈ [symbol] ⁿ^{_{g}} represents the vector of optimization constraint functions, R∈ [symbol] ⁿ^{ᵤ} indicates a residual vector due to numerical discretization applied to the governing physics expressed using partial differential equations (PDEs), and u∈ [symbol] ⁿ^{ᵤ} denotes the vector of state variables. x:=[x₁, . . . , xₙ_{ₓ}]^{T} is a vector of continuous design variables and c:=[c₁, . . . , cₙ_{_{c}}]^{T} is the vector of categorical design variables. lbᵢ and ubᵢ, i=1, . . . , nₓ, refer to the lower and upper bounds of the continuous variable xᵢ. Nᵢ, i=1, . . . , n_{c} is the number of choices available for the categorical variable cᵢ. The choices for each cᵢ, i=1, . . . , n_{c}, are indexed as {1, . . . , Nᵢ}.

Depending on the design problem being solved, J, g and R can be linear or nonlinear functions with corresponding arguments. J, g, and R are both continuous and differentiable. Because the sensitivities ∇_{c}J and ∇_{c}g for categorical design variables c are non-differentiable, optimizer 220 reparametrizes categorical design variables c and takes the probability of using reparametrized categorical design variables c as the corresponding design variables. In other words, instead of using discrete values for categorical design variables c, optimizer 220 converts categorical design variables c to corresponding continuous design variables. The optimizer 220 reparametrizes the optimization functions using the probabilities of categorical design variables c using Equation 2. The sensitivity analysis is then carried out with respect to reparametrized optimization functions.

$$\\ \begin{matrix}{min}_{x , θ} {}_{} J ( u ( x , θ ) , x , θ ) subject to R ( u ( x , θ ) , x , θ ) = 0 , & Equation 2\end{matrix}$$

$$\\ g ( u ( x , θ ) , x , θ ) \leq 0 , {lb}_{i} \leq {x}_{i} \leq {ub}_{i} , i = 1 , … , {n}_{x} ,$$

where

$$\\ θ := {[ {θ}_{1 , 1} , … , {θ}_{1 , {N}_{1}} , {θ}_{2 , 1} , … , {θ}_{2 , {N}_{2}} , … , {θ}_{{n}_{c} , 1} , … , {θ}_{{n}_{c} , {N}_{{n}_{c}}} ]}^{T}$$

denotes the vector of unnormalized log-probabilities of the categorical variables. The first and second indices in θ_{i,j} refer, respectively, to the variable index i and a variable available choice j. For example, a categorical design variable i where the probability of using each of the Nᵢ choices for the categorical design variable i are defined by pᵢ: =[p_{i,1}, . . . , p_{i,N}_{ᵢ}]^{T}, θ_{i,j} is calculated using Equation 3.

$$\\ \begin{matrix}{θ}_{i , j} = log it ( {p}_{i , j} ) := ln ( \frac{{p}_{i , j}}{1 - {p}_{i , j}} ) , j = 1 , … , {N}_{i} & Equation 3\end{matrix}$$

where p_{i,j} is the likelihood of choice j for categorical variable i. Unnormalized log-probabilities θ_{i,j}, i=1, . . . , n_{c}, j=1, . . . , Nᵢ can be used as the design variables instead of the corresponding probabilities p_{i,j}. Once the optimal values of θ_{i,j}'s are found, corresponding optimal probabilities p_{i,j} can be computed using the Softmax function using Equation 4.

$$\\ \begin{matrix}{p}_{i , j} = {( softmax ( {θ}_{i} ) )}_{j} := \frac{exp ( {θ}_{i , j} )}{{\sum }_{k = 1}^{{N}_{i}} exp ( {θ}_{i , k} )} , & Equation 4\end{matrix}$$

$$\\ i = 1 , … , {n}_{c} , j = 1 , … , {N}_{i}$$

In order to utilize gradient-based optimizers, optimizer 220 computes the sensitivities of the objective and constraint functions with respect to θ and x (e.g., ∇ₓJ, ∇x_{g}, ∇_{θ}J and ∇_{θ}g). For all categorical variables, optimizer 220 uses a sampling process to select a sample from each of the choices based on the probabilities. Optimizer 220 then computes the values of J and g using the selected sample. The sampling process, however, can impact the differentiability of these functions. Optimizer 220 resolves the non-differentiability of the sampling technique using a Gumbel-Softmax Method (GSM). The GSM method allows for the selection of differentiable samples from categorical distributions.

Objective function J is not an explicit function of θ but rather the continuous attributes (properties) of a sample (e.g., a choice). The sample is selected from the categorical distribution function characterized by θ. Once a sample is selected from the categorical distribution of θ, the value of J is computed using the properties of the selected sample. A categorical distribution function is a discrete probability distribution specifying the likelihood of the choices for a categorical design variable. For instance, by applying Equation 4, the categorical distribution of θ is a vector p_{θ}:={(softmax(θ))₁, . . . , (softmax(θ))_{N}}. A one-hot sample vector s can then be generated from p_{θ} with size N in which all sample vector entries are zero except for the index corresponding to the selected choice for which the entry is one. Attributes of the selected choice are collected in a vector a. Because J is a function of θ through the sample and the attributes, J can be formulated as J(a(s(θ))). The sensitivity of J with respect to θ can be expressed using Equation 5. The sensitivity of each constraint function gᵢ uses a similar function.

∇_{θ}J=(∇_{θ}a)^{T}∇ₐJ=(∇ₛa∇_{θ}s)^{T}∇ₐJ Equation 5

The sample vector s is not differentiable with respect to θ. Optimizer 220 uses the GSM method to make a differentiable soft one-hot sample vector \tilde{s} according to Equation 6, which approximates sample vector s and has the same distribution as the categorical distribution associated with θ (e.g., s˜p_{θ}). Optimizer 220 then calculate ∇_{θ}s of J and g using sample vector s.

$$\\ \begin{matrix}{\tilde{s}}_{i} := \frac{exp ( ( {θ}_{i} + {G}^{{}_{} ( i )} ) / τ )}{{\sum }_{j = 1}^{N} exp ( ( {θ}_{j} + {G}^{{}_{} ( j )} ) / τ )} , i = 1 , … , N & Equation 6\end{matrix}$$

Equation 6 can also be expressed as \tilde{s}=softmax((θ+G)/τ) with G: =[G⁽¹⁾, . . . , G^{(N)}]^{T}. For each class index i, the noise G(i) can be obtained by independently sampling the Gumbel distribution Gumbel(0, 1). For this purpose, optimizer 220 selects a uniformly distributed random real number r and settingG(i)=−ln(−ln(r)). Temperature parameter τ is relaxation parameter that approximates how closely \tilde{s} follows the pedistribution. At the beginning of the optimization routine, optimizer 220 sets τ to a high temperature (in a relative sense), and uses an annealing scheme to reduce the value of τ to a small non-zero value as the optimization progresses. For example, the annealing scheme to reduce τ can be exponential or logarithmic. Smaller values of τ cause the samples generated by the GSM method to more closely match the p_{θ} distribution.

Soft one-hot sample vector \tilde{s} includes multiple choices for categorical design variables. Multiple choices in sample vector \tilde{s} cause problems when evaluating objective function J and the sensitivities ∇_{c}J. Optimizer 220 addresses this problem by converting the soft one-hot sample vector \tilde{s} into a true one-hot sample vector ŝ using Equation 7.

$$\\ \begin{matrix}\hat{s} := 𝒥 ( {arg max}_{i ∈ \{ 1 , … , N \}} {\tilde{s}}_{i} ) & Equation 7\end{matrix}$$

Because s is not differentiable with respect to θ, ∇_{θ}\tilde{s} instead of ∇_{θ}ŝ is utilized. As the optimization advances and \tilde{s} approaches the true one-hot vector ŝ, the discrepancy between ∇_{θ}\tilde{s} and ∇_{θ}ŝ diminishes. Optimizer 220 then generates the gradient of J with respect to θⱼ=1, . . . , N using Equation 8.

$$\\ \begin{matrix}∇ {}_{{θ}_{j}} J = ∇ {}_{{θ}_{j}} a \cdot ∇ {}_{a} J = ( ∇ {}_{\tilde{s}} a ∇ {}_{{θ}_{j}} \tilde{s} ) \cdot ∇ {}_{a} J = ∇ {}_{a} J \cdot {\sum }_{i = 1}^{N} \frac{\partial a}{\partial {\tilde{s}}_{i}} \frac{\partial {\tilde{s}}_{i}}{\partial {θ}_{j}} , & Equation 8\end{matrix}$$

$$\\ j = 1 , … , N , where \frac{\partial {\tilde{s}}_{i}}{\partial {θ}_{j}} = \{ \begin{matrix}( 1 - {\tilde{s}}_{i} ) {\tilde{s}}_{i} , & if i = j \\ - {\tilde{s}}_{i} {\tilde{s}}_{j} , & otherwise\end{matrix} ,$$

During each optimization iteration, optimizer 220 determines ∇ₐJ which is the sensitivity of J with respect to a, where a is associated with the continuous attributes of the sample vector \tilde{s} with the highest unnormalized log-probability. Because objective function J is a function of continuous design variables xₗ (and reparametrized categorical design variables θₘ) through u, the gradient of J with respect to xₗ is determined using Equation 9.

$$\\ \begin{matrix}∇ {}_{{x}_{l}} J = \frac{\partial J}{\partial {x}_{l}} + ∇ {}_{{x}_{l}} u \cdot ∇ {}_{u} J , l = 1 , … , {n}_{x} & Equation 9\end{matrix}$$

where ∂J/∂xₗ and ∇ᵤJ are derivatives of J with respect to xₗ and u, respectively. Optimizer 220 computes ∂ⱼ/∂xₗ and ∇ᵤJ from the objective function J. Using the discretized governing equation R (u(x, θ), x, θ)=0 and differentiating R with respect to xₗ yields Equation 10.

$$\\ \begin{matrix}\frac{\partial R}{\partial {x}_{l}} + ∇ {R}_{u} ∇ {}_{{x}_{l}} u = 0 & Equation 10\end{matrix}$$

Because the right-hand side of Equation 10 is zero, multiplying Equation 10 by any arbitrary vector of a conforming size to the governing equation R also results in zero. The multiplier vector, which is often called an adjoint vector λ_{J}∈ [symbol] ⁿ^{ᵤ}. Applying λ_{J} to Equation 10 and combining with Equation 9 results in Equation 11.

$$\\ \begin{matrix}∇ {}_{{x}_{l}} J = \frac{\partial J}{\partial {x}_{l}} + ∇ {}_{{x}_{l}} u \cdot ∇ {}_{u} J - {λ}_{J} \cdot ( \frac{\partial R}{\partial {x}_{l}} + ∇ {R}_{u} ∇ {}_{{x}_{l}} u ) , l = 1 , … , {n}_{x} & Equation 11\end{matrix}$$

Equation 11 holds independent of the value of λ_{J}. λ_{J} is chosen so that ∇ₓ_{ₗ}u in Equation 11 vanishes using Equation 12, which reduces a complexity of the computation of the gradient of the objective function J with respect to the continuous design variables x.

∇Rᵤ^{T}λ_{J}=∇ᵤJ Equation 12

Once λ_{J} is determined using Equation 12, Equation 11 reduces to Equation 13.

$$\\ \begin{matrix}∇ {}_{{x}_{l}} J = \frac{\partial J}{\partial {x}_{l}} - {λ}_{J} \cdot \frac{\partial R}{\partial {x}_{l}} , l = 1 , … , {n}_{x} & Equation 13\end{matrix}$$

Optimizer 220 uses Equation 13 to compute the sensitivity of J with respect to the continuous design variables xₗ. As shown, there are no dependence on xₗ or any other continuous design variable in Equation 12. Optimizer 220 only solves Equation 12 one time and does not have to solve Equation 12 for each continuous design variable individually. The adjoint for each constraint function gᵢ, i=1, . . . , n_{g} is determined using Equation 14.

∇Rᵤ^{T}λ_{g}_{ᵢ}=∇ᵤgᵢ Equation 14

Optimizer 220 then computes ∇_{\tilde{s}}a in Equation 8 for each entry of \tilde{s}ₘ, where \tilde{s}ₘ is the sample vector drawn from the categorical probability distribution characterized by θₘ employing the GSM method. Each entry of \tilde{s}ₘ corresponds to a choice which can be characterized by some continuous attributes (properties). All the choices considered for a categorical variable are characterized using the same set of attributes. Suppose \tilde{s}ₘ corresponds to a categorical variable with Nm choices. Let aₖ:=[a_{1,k}, . . . , aₙ_{ₘ}ₖ], k=1, . . . , Nₘ be the vector of size nₘ containing the continuous attributes of each choice. An attribute matrix for the categorical variables Aₘ∈ [symbol] ⁿ^{ₘ}^{×N}^{ₘ} is determined using Equation 15.

$$\\ \begin{matrix}{A}_{m} := [ \begin{matrix}{a}_{1 , 1} & ⋯ & {a}_{1 , {N}_{m}} \\ ⋮ & ⋱ & ⋮ \\ {a}_{{n}_{m} , 1} & ⋯ & {a}_{{n}_{m} , {N}_{m}}\end{matrix} ] & Equation 15\end{matrix}$$

If \tilde{s}ₘ is a hard one-hot vector, the attributes of the selected choice in this categorical variable can be determined using Equation 16.

a=Aₘ\tilde{s}ₘ Equation 16

During the sensitivity analysis for ∇_{\tilde{s}}a optimizer 220 uses Equation 16 to compute ∇_{\tilde{s}}_{ₘ}a=Aₘ where a is associated with the continuous attributes of the sample vector \tilde{s} with the highest unnormalized log-probability.

Inserting ∇_{\tilde{s}}_{ₘ}a in the gradient of objective function J with respect to categorical design variable probabilities results in Equation 17, where ∇ₐJ is the gradient of the objective function J with respect to a.

∇_{θ}_{ₘ}J=∇ₐJ·(∇_{\tilde{s}}_{ₘ}a∇_{θ}_{ₘ}\tilde{s}ₘ)=∇ₐJ·(Aₘ∇_{θ}_{ₘ}\tilde{s}ₘ), m=1, . . . ,n_{c}, Equation 17

Because a is a continuous variable, computing ∇ₐJ can be computed using an adjoint method similar to the adjoint method used to compute the gradient of objective function J with respect to xₗ by using Equation 18 to compute ∇ₐJ for PDE-constrained design problems. Optimizer 220 also uses a similar equation to compute the gradient of constraint function(s) g with respect to a as ∇ₐg.

$$\\ \begin{matrix}∇ {}_{{a}_{l}} J = \frac{\partial J}{\partial {a}_{l}} - {λ}_{J} \cdot \frac{\partial R}{\partial {a}_{l}} , l = 1 , … , {n}_{x} & Equation 18\end{matrix}$$

When optimizer 220 solves a design problem for linear elasticity applications, such as the design of a frame structure, optimizer 220 uses a variation of the objective function J from Equation 1. More specifically, optimizer 220 uses the objective function J of Equation 19.

$$\\ \begin{matrix}{min}_{x , c} {}_{} J ( u ( x , c ) , x , c ) subject to K ( x , c ) u ( x , c ) = f ( x , c ) , & Equation 19\end{matrix}$$

$$\\ g ( u ( x , c ) , x , c ) \leq 0 , {lb}_{i} \leq {x}_{i} \leq {ub}_{i} , i = 1 , … , {n}_{x} ,$$

$$\\ {c}_{i} ∈ \{ 1 , … , {N}_{i} \} , i = 1 , … , {n}_{c} .$$

where K∈ [symbol] ⁿ^{ᵤ}^{×n}^{ᵤ} indicates the structure's stiffness matrix, f∈ [symbol] ⁿ^{ᵤ} specifies the external load vector, and u∈ [symbol] ⁿ^{ᵤ} denotes the vector of nodal displacements (state variables). Similar to Equation 1, Equation 19 can be reparametrized to replace categorical design variables c with the probabilities θ. Similar to equations 9-14 for PDE-constrained design problems, optimizer 220 uses the discretized frame structure governing equation K u−f=0 and differentiating the governing function with respect to xₗ, which results in Equation 20.

K∇ₓ_{ₗ}u+(∇ₓ_{ₗ}K)u−∇ₓ_{ₗ}f=0 Equation 20

Where optimizer 220 assumes the external force vector f is only a function of xₗ not u. Because the right-hand side of Equation 20 is zero, multiplying Equation 20 by any arbitrary vector of a conforming size to the governing equation also results in zero. Denote the multiplier vector, called the adjoint variable vector, by λ_{J}∈ [symbol] ⁿ^{ᵤ}. Applying Equation 20 to Equation 9 results in Equation 21.

$$\\ \begin{matrix}∇ {}_{{x}_{l}} J = \frac{\partial J}{\partial {x}_{l}} + ∇ {}_{{x}_{l}} u \cdot ∇ {}_{u} J - {λ}_{J} \cdot ( K ∇ {}_{{x}_{l}} u + ( ∇ {}_{{x}_{l}} K ) u - ∇ {}_{{x}_{l}} f ) , & Equation 21\end{matrix}$$

$$\\ l = 1 , … , {n}_{x}$$

Equation 21 holds regardless of the value of λ_{J}. For example, λ_{J} can be chosen such that ∇ₓ_{ₗ}u in Equation 21 vanishes using Equation 22.

Kλ_{J}=∇ᵤJ Equation 22

Once λ_{J} is determined using Equation 22, Equation 21 reduces to Equation 23.

$$\\ \begin{matrix}∇ {}_{{x}_{l}} J = \frac{\partial J}{\partial {x}_{l}} - {λ}_{J} \cdot ( ( ∇ {}_{{x}_{l}} K ) u - ∇ {}_{{x}_{l}} f ) , l = 1 , … , {n}_{x} & Equation 23\end{matrix}$$

The adjoint for each constraint function gᵢ, i=1, . . . , n_{g} is determined using Equation 24.

Kλ_{g}_{ᵢ}=∇ᵤgᵢ Equation 24

Optimizer further uses Equation 25 to compute the gradient of objective function J with respect to a as ∇ₐJ for linear elasticity design problems. Optimizer also uses a similar equation to compute gradient of constraint function(s) g with respect to a as ∇ₐg.

$$\\ \begin{matrix}∇ {}_{{a}_{l}} J = \frac{\partial J}{\partial {a}_{l}} - {λ}_{J} \cdot ( ( ∇ {}_{{a}_{l}} K ) u - ∇ {}_{{a}_{l}} f ) , l = 1 , … , {n}_{x} & Equation 25\end{matrix}$$

Visualizer 222 displays the impact of each categorical design variable on a design via a user interface. Visualizer 222 displays a model of the design problem. Visualizer 222 then applies a colormap to display the sensitivities of a categorical design variable choice for the design members on the objective function for the design solution. Each color in the colormap corresponds to how sensitive different design members of the design solution are to the choices for a categorical design variable c. Visualizer 222 further allows the user to select different design members in the design solution to obtain further information on the sensitivities of that design member to categorical design variable choices. When the user selects a design member, such as by clicking on the design member, hovering the cursor over the design member, and/or the like, visualizer 222 then presents different options to the user for presenting sensitivities and probabilities for the categorical design variable and/or the choices for the categorical design variable for that design member. For example, visualizer 222 can provide the user with a pop-up menu providing the various options to select from, such as tables, lists, pie charts, bar charts and stacked bar charts to show the impact of each variable/choice on the objective function for each member in model of design problem and the probabilities of each choice being selected for the categorical design variable. Once the user selects an option, visualizer 222, then provides the user with the requested information using the selected option. For example, if the user selects an option to see the probabilities using a pie chart, a pop window or inset can be displayed showing a pie chart with a size of each wedge indicating a probability of a corresponding choice for the categorical design variable. Visualizer 222 can also provide user interface elements for sorting the displayed information.

Storage 204 includes non-volatile storage for applications and data, and can include fixed or removable disk drives, flash memory devices, and CD-ROM, DVD-ROM, Blu-Ray, HD-DVD, or other magnetic, optical, or solid state storage devices. Input data 218, optimizer 220, visualizer 222 can be stored in storage 204 and loaded into memory 202 when executed.

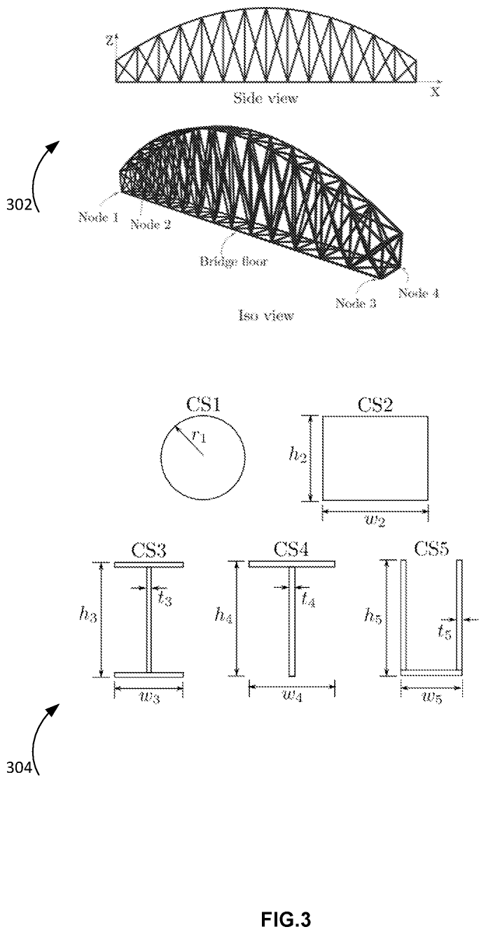

FIG. 3 shows an example of a design problem with categorical design variables according to various embodiments. The design problem in FIG. 3 corresponds to the design of a bridge structure 302. Bridge structure 302 is shown in both side and Isometric views. Bridge structure 302 is composed of 258 truss elements (design members) modeled by Euler-Bernoulli beam elements. For example, bridge structure 302 could span 14 meters along the X axis, has a width of one meter and a maximum height of 3.45 meters. All of the design members of bridge structure 302 are made of steel with a Young's modulus of 210 GPa, yield stress of 360 MPa and Poisson's ratio of 0.3. The design members lying on the floor of the bridge structure 302 are subject to a downward (along the negative Z axis) uniform load of 1000 Newton per meter. Furthermore, the entire bridge structure 302 is under a gravity load. Bridge structure 302 is clamped at nodes one to four.

Optimizer 220 considers various design problems, for example minimizing the total strain energy of bridge structure 302 due to the applied loads. The maximum stress in all elements of bridge structure 302 should also remain below a yield strength for each design member. In this design problem, optimizer 220 considers a combination of continuous and categorical design variables. The continuous variables include the orientation of the 258 beam members and the length of the beams not lying on the floor of the bridge structure 302 (187 beams in total). Hence, there are 445 continuous design variables. The categorical design variables include the cross-sectional beam choices 304 of the design members which can be changed independently of each other (e.g., five cross-sectional beam choices 304 are shown in FIG. 3). Each cross-sectional beam choice 304 has one or many physical attributes, such as height, width, thickness, radius, etc. as shown by the various t, h, w, and r parameters for cross-sectional beam choices 304.

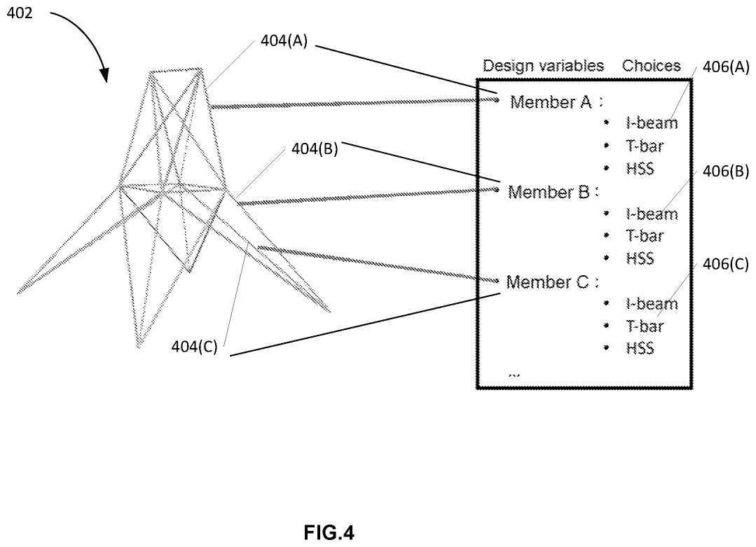

FIG. 4 shows another example of a design problem with categorical design variables according to various embodiments. The design problem in FIG. 4 corresponds to the design of a truss 402. As shown, truss 402 includes several design members (e.g., beams) including representative design members 404(A), 404(B) and 404(C). Each design member 404 can have a combination of continuous and categorical design variables. As further shown in FIG. 4, each of design members 404(A)-(C) have a categorical design variable for a beam type as shown by the categorical design variable choices 406(A)-(C) of I-beam, T-bar, and hollow structural section (HSS).

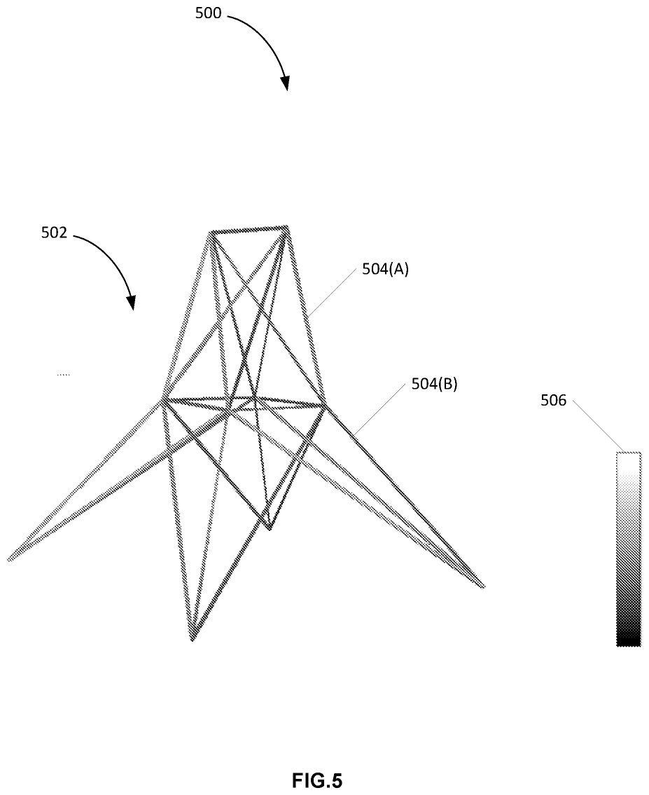

FIG. 5 shows an example of a user interface 500 for visualizing the design problem of FIG. 4 according to various embodiments. As shown in FIG. 5, user interface 500 includes, without limitation a graphical depiction 502 of truss 402 and a color bar 506. The graphical depiction 502 also includes a depiction of each design member including representative design members 504(A) and 504(B). Visualizer 222 renders each of the design members 504 using a color or intensity that corresponds to how sensitive the objective function for the design problem is to the choices for the categorical design variables for a corresponding design member 504. For example, the sensitivity of the objective function to the categorical design variable choices for a design member 504 can be computed as an aggregation (e.g., a Euclidean norm) of the gradients of the objective function with respect to each categorical design variable choice for the design member 504. Color bar 506 shows the range of colors used to represent the various sensitivities of design members 504. As shown, design members 504 for which the objective function has a higher sensitivity to the categorical design variable choices are shown in the colors at the upper end of color bar 506 and design members 504 for which the objective function has a lower sensitivity to the categorical design variable choices are shown in the colors at the lower end of color bar 506. For example, as shown in FIG. 5, the objective function is more sensitive to the categorical design variable choices for design member 504(A) than the categorical design variable choices for design member 504(B).

Visualizer 222 allows a user to select different design members 504 in graphical depiction 502 in order to obtain further information on the sensitivities and/or probabilities of the categorical design variable choices for the design members 504. The user selects a design member (e.g., 504(A) or 504(B)), by clicking on the design member 504, hovering the cursor over the design member 504, and/or the like. Visualizer 222 then provides the user with a pop-up menu providing a plurality of options that the user can select from to get more information on the sensitivities and/or probabilities of the design member 504. For example, the options could include various tables, lists, pie charts, bar charts, stacked bar charts, and/or the like for displaying the probabilities of each categorical design choice appearing in a solution to the design problem or the sensitivity of the objective function to the categorical design variable choices.

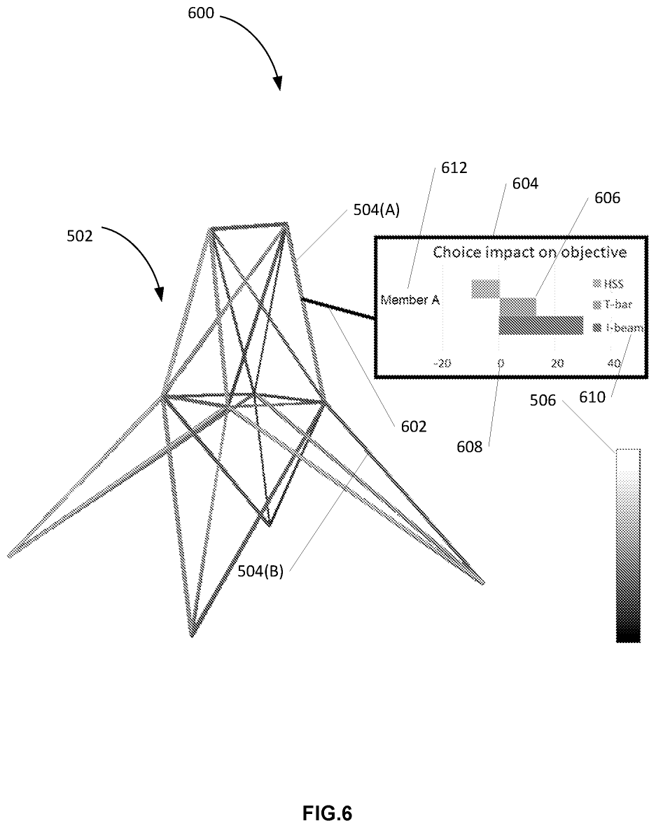

FIG. 6 shows another example of a user interface 600 for visualizing the design problem of FIG. 4 according to various embodiments. As shown in FIG. 6, user interface 600 includes, without limitation, the graphical depiction 502 of truss 402, color bar 506, a callout link 602, and a pop-up window 604. Pop-up window 604 includes, without limitation, a bar chart 606, a range axis 608, categorical design variable choices 610, and a design member label 612. The graphical depiction 502 also includes a depiction of each design member including representative design members 504(A) and 504(B). Visualizer 222 renders each of the design members 504 using a color or intensity consistent with what is described in FIG. 5. Color bar 506 shows the range of colors used to represent the various sensitivities of design members 504. Visualizer 222 uses callout link 602 to indicate that pop-up window 604 is associated with the design member 504(A) as further identified in design member label 612 (e.g., for design member 504(A) as shown). Visualizer 222 uses pop-up window 604 to display the overall impact of each categorical design variable choice 610 on the objective function. As shown, each categorical design variable choice 610 (HSS, T-bar, and I-beam) is shown using a different color. The length of each colored bar in bar chart 606 and the position of the bar along range axis 608 indicates the impact of the corresponding categorical design variable choice 610 on the objective function. For example, for the categorical design variable choice 610 corresponding to the choice of HSS, the shorter length of the corresponding colored bar in bar chart 606 indicates that the choice of HSS has a lower impact on the objective function. The position of HSS bar in the negative side of range axis 608 indicates that the choice of HSS lowers the objective function value. Similarly for the categorical design variable choice 610 corresponding to the choice of T-bar, the medium length of the corresponding colored bar in bar chart 606 indicates that the choice of T-bar has a medium impact on the objective function. The position of T-bar in the positive side of range axis 608 indicates that the choice of T-bar increases the objective function value. For the categorical design variable choice 610 corresponding to the choice of I-bar, the large length of the corresponding colored bar in bar chart 606 indicates that the choice of I-bar has a large impact on the objective function. The position of I-bar bar in the positive side of range axis 608 indicates that the choice of I-bar increases the objective function value.

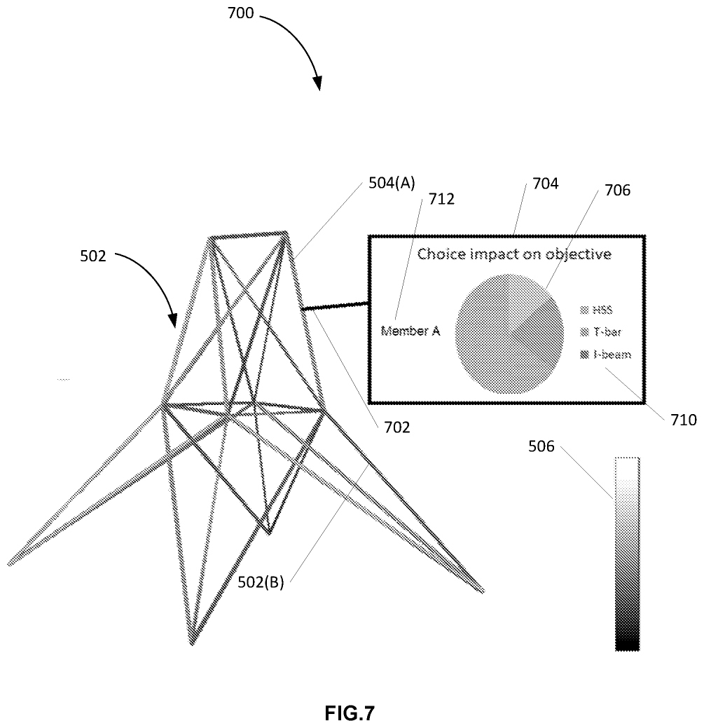

FIG. 7 shows another example of a user interface 700 for visualizing the design problem of FIG. 4 according to various embodiments. User interface 700 includes, without limitation, graphical depiction 502, color bar 506, callout link 702, and pop-up window 704. Pop-up window 704 includes, without limitation, pie chart 706, categorical design variable choices 710 and design member label 712. The graphical depiction 502 also includes a depiction of each design member including representative design members 504(A) and 504(B). Visualizer 222 renders each of the design members 504 using a color or intensity consistent with what is described in FIG. 5. Color bar 506 shows the range of colors used to represent the various sensitivities of design members 504. Visualizer 222 uses callout link 702 to indicate that pop-up window 704 is associated with the design member 504(A) as further identified in design member label 712 (e.g., for design member 504(A) as shown). Visualizer 222 uses pop-up window 704 to display the impact of each categorical design variable choice 710 on the objective function. As shown, each categorical design variable choice 710 (HSS, T-bar, and I-beam) is shown using a different color. The size of each colored slice in pie chart 706 indicates the impact of the corresponding categorical design variable choice 710 on the objective function. For example, for the categorical design variable choice 710 corresponding to the choice of HSS, the smaller size of the corresponding colored slice in pie chart 706 indicates that the choice of HSS has a lower impact on the objective function. Similarly for the categorical design variable choice 710 corresponding to the choice of I-bar, the medium size of the corresponding colored slice in pie chart 706 indicates that the choice of I-bar has a medium impact on the objective function. For the categorical design variable choice 710 corresponding to the choice of T-bar, the large size of the corresponding colored slice in pie chart 706 indicates that the choice of T-bar has a large impact on the objective function.

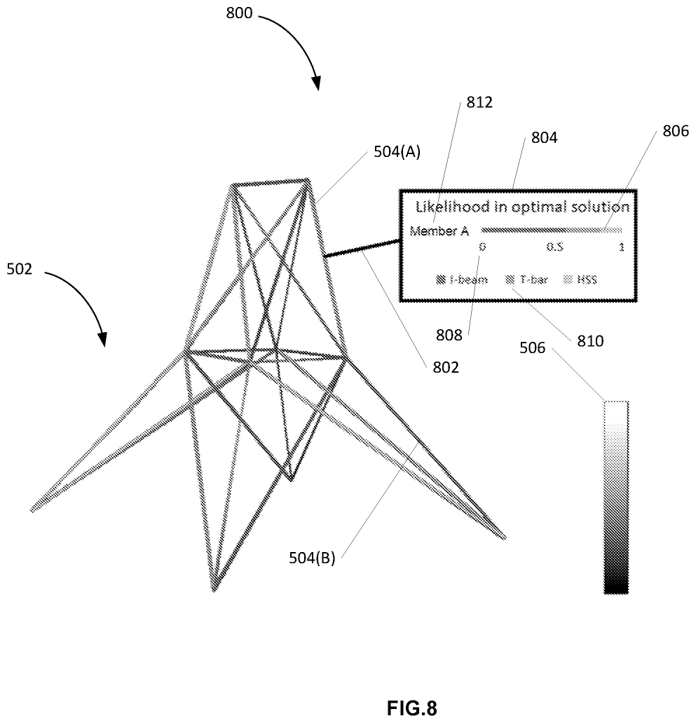

FIG. 8 shows another example of the user interface 800 for visualizing the design problem of FIG. 4 according to various embodiments. The user interface includes, without limitation, graphical depiction 502, color bar 506, callout link 802, pop-up window 804, stacked bar chart 806, range axis 808, categorical design variable choices 810 and design member label 812. The graphical depiction 502 also includes a depiction of each design member including representative design members 504(A) and 504(B). Visualizer 222 renders each of the design members 504 using a color or intensity consistent with what is described in FIG. 5. Color bar 506 shows the range of colors used to represent the various sensitivities of design members 504. Visualizer 222 uses callout link 802 to indicate that pop-up window 804 is associated with the design member 504(A) as further identified in design member label 812 (e.g., for design member 504(A) as shown). Visualizer 222 uses pop-up window 804 to display the likelihood of each categorical design variable choice 810 being selected in the optimal solution for the design problem. As shown, each categorical design variable choice 810 (HSS, T-bar, and I-beam) is shown using a different color. In stacked bar chart 806, the length of each colored bar along range axis 808 indicates the likelihood of the corresponding categorical design variable choice 810 being selected in the optimal solution. For example, for the categorical design variable choice 810 corresponding to the choice of I-beam, the shorter length of the corresponding colored bar in stacked bar chart 806 indicates that the choice of I-bar has a lower likelihood of being selected in the optimal solution to the design problem. Similarly for the categorical design variable choice 810 corresponding to the choice of T-bar, the medium length of the corresponding colored bar in stacked bar chart 806 indicates that the choice of T-bar has a medium likelihood of being selected in the optimal solution to the design problem. For the categorical design variable choice 810 corresponding to the choice of HSS, the longer length of the corresponding colored bar in stacked bar chart 806 indicates that the choice of HSS has a high likelihood of being selected in the optimal solution to the design problem.

Visualizer 222 can also visualize the overall impact of each categorical design variable choice (e.g., HSS, T-bar, and I-beam) on the objective function using a table. Similar to FIGS. 6-8 visualizer 222 uses a callout link to indicate that a pop-up window is associated with the design member 504. Visualizer 222 uses the pop-up window to display a table with multiple rows. For example, each categorical design variable choice 610 can be shown in a different row and the corresponding impact on the objective function can be shown in a column of the table. Visualizer 222 can also include the likelihood of each of the choices for the categorical design variable being selected in the optimal solution in another column of the table.

Similarly visualizer 222 can visualize the overall impact of each categorical design variable choice (e.g., HSS, T-bar, and I-beam) on the objective function using a list. Visualizer 222 can use a pop-up window to display a list of categorical design variables separated with a comma or other delimiter or separator with the corresponding impact of the choices for the categorical design member on the objective function. Visualizer 222 can also include the likelihood of each of the choices for the categorical design variable being selected in the optimal solution to the list for each categorical design variable.

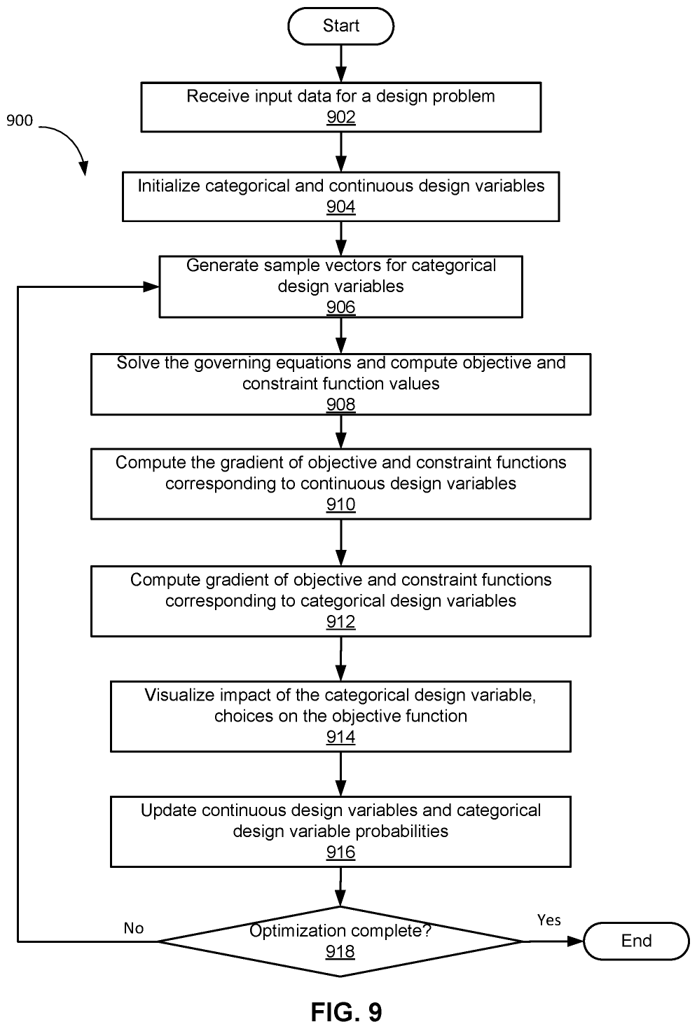

FIG. 9 sets forth a flow diagram of method steps for optimizing a design problem with categorical design variables, according to various embodiments. Although the method steps are described in conjunction with FIGS. 1-8, persons skilled in the art will understand that any system configured to perform the method steps, in any order, falls within the scope of the present disclosure.

As shown, a method 900 begins at step 902 where optimizer 220 receives input data 218 for a design problem. For example, optimizer 220 receives an objective function J, one or more constraint functions g, continuous design variables x, bounds for the continuous design variables x, categorical variables c, available choices for the categorical variables c, and a temperature parameter τ for a simulated annealing process.

At step 904, optimizer 220 initializes continuous design variables x and categorical design variables c. Each continuous design variable xᵢ is set to an initial value within the corresponding bounds for the design variable xᵢ, such as by selecting a random value within the bounds. Each available choice for each categorical design variable cᵢ is assigned an equal probability or alternatively a random probability.

At step 906, optimizer 220 generates a sample vector ŝ for each categorical design variable using the GSM method. For each of the N categorical variables i optimizer 220 repeats the following three steps. First, optimizer 220 generates independent and identically distributed samples or Gumbel noises G⁽ⁱ⁾ from the standard Gumbel distribution Gumbel(0,1). Second, optimizer 220 computes a soft one-hot sample vector si using Equation 6 for each of the Nᵢ choices for the categorical design variable. The Gumbel noises in Equation 6 makes the sample vector s continuous and differentiable with respect to categorical design variable probabilities θ. Due to relaxation parameter τ in Equation 6, the resulting soft one-hot sample vector \tilde{s} does not exactly follow distribution of θ. However as the value of τ gets smaller over the design iterations, the soft one-hot sample vector \tilde{s} becomes a true one-hot vector. Third, optimizer 220, computes true one-hot sample vector ŝ from \tilde{s} using Equation 7.

At step 908, optimizer 220 solves the governing equations and computes the objective and constraint function values. For PDE-constrained design problems, optimizer 220 solves the governing equation R (u(x, θ), x, θ)=0 to find state variables u. Governing equation R indicates the residual vector due to the numerical discretization applied to the governing physics PDEs. Optimizer 220 numerically solves the discretized governing equation R of Equation 2 by replacing categorical design variable probabilities θ with sample vector ŝᵢ, i=1, . . . , N computed during step 906. After finding state variables u, optimizer 220 computes objective function value J and constraint function value(s) g using Equation 2, state variable u, and sample vector si used in place of categorical design variable probabilities θ. For linear elasticity design problems, optimizer 220 solves the discretized governing equation K u=f to find the vector of nodal displacements u. In the governing equation, K indicates the structure's stiffness matrix and f specifies the external load vector. Optimizer 220 numerically solves the discretized governing equation K u=f of the reparametrized version of Equation 19 by replacing categorical design variable probabilities θ with sample vector ŝᵢ, i=1, . . . , N computed during step 906. After finding the vector of nodal displacements u, optimizer 220 computes objective function value J and constraint function value(s) g using the reparametrized version of Equation 19, the vector of nodal displacements u, and sample vector si used in place of categorical design variable probabilities θ.

At step 910, optimizer 220 computes the gradient of the objective and constraint functions corresponding to the continuous design variables. Optimizer 220 numerically computes the gradient of objective function J with respect to state variable u as (∇ᵤJ) based on the objective function J. Optimizer 220 also numerically computes the gradient of constraint functions gᵢ, i=1, . . . , n_{g} with respect to state variable u as ∇ᵤgᵢ based on the constraint function(s) g.

For PDE-constrained design problems, optimizer 220 calculates adjoint vector λ_{J} so as to cause the ∇ₓ_{ₗ}u term in Equation 11 to vanish. Optimizer 220 then calculates adjoint vectors λ_{g}_{ᵢ} in a similar manner as adjoint vector λ_{J}. Next, optimizer 220 calculates derivatives of objective function J, constraint function(s) g, and governing function R with respect to continuous variables xₗ, l=1, . . . , nₓ as ∂J/∂xₗ, ∂g/∂xₗ, and ∂R/∂xₗ, respectively, based on the formulations for objective function J, constraint function(s) g, and governing function R. Optimizer 220 then computes the gradient of objective function J with respect to continuous design variables x as ∇ₓJ using Equation 11. Finally, optimizer 220 computes the gradient of constraint function(s) g with respect to continuous design variables x as ∇ₓg.

For linear elasticity design problems, optimizer 220 calculates adjoint vector λ_{J} so as to cause the ∇ₓ_{ₗ}u term in Equation 21 to vanish. Optimizer 220 then calculates adjoint vectors λ_{g}_{ᵢ} in a similar manner as adjoint vector λ_{J}. Next, optimizer 220 calculates derivatives of objective function J, constraint function(s) g, stiffness matrix K, and external load vector f with respect to continuous variables xₗ, l=1, . . . , nₓ as ∂J/∂xₗ, ∂g/∂xₗ, ∂K/∂xₗ, and ∂f/∂xₗ, respectively, based on the formulations for objective function J, constraint function(s) g, stiffness matrix K, and external load vector f. Optimizer 220 then computes the gradient of objective function J with respect to continuous design variables x as ∇ₓJ using Equation 23. Finally, optimizer 220 computes the gradients of constraint function(s) g with respect to continuous design variables x as ∇ₓg.

At step 912, optimizer 220 computes gradients of the objective and constraint functions corresponding to the categorical design variables. For each categorical design variable, optimizer 220 first forms attribute matrix A using Equation 15 based on the various continuous attributes for each categorical design variable choice.

For PDE-constrained design problems, optimizer 220 calculates derivatives of objective function J, constraint function(s) g, and governing function R with respect to attributes of the selected class categorical variable aₗ as ∂J/∂aₗ, ∂g/∂aₗ, and ∂R/∂aₗ, respectively based on the formulations for objective function J, constraint function(s) g, and governing function R. Optimizer 220 also numerically computes the gradient of categorical design variable attributes a with respect to sample vector \tilde{s} as ∇_{\tilde{s}}a. Optimizer 220 then uses adjoint vectors λ_{J} and λ_{g} computed during step 908 to compute the gradient of objective function J with respect to aₗ as ∇ₐ_{ₗ}J using Equation 18. Optimizer 220 then computes the gradient of the objective function J with respect to the categorical design variable probabilities θⱼ as ∇_{θ}_{ⱼ}J using Equation 17. A similar approach is used to compute the gradient of constraint function(s) g is then computed similarly as ∇ₐ_{ₗ}g and the gradient of constraint function(s) g with respect to the categorical design variable probabilities θⱼ as ∇_{θ}_{ⱼ}g.

For linear elasticity design problems, optimizer 220 calculates derivatives of objective function J, constraint function(s) g, and governing function R with respect to attributes of the selected class categorical variable aₗ as ∂J/∂aₗ, ∂g/∂aₗ, and ∂R/∂aₗ, respectively based on the formulations for derivatives of objective function J, constraint function(s) g, stiffness matrix K and external load vector f. Optimizer 220 also numerically computes the gradient of categorical design variable attributes a with respect to sample vector \tilde{s} as ∇_{\tilde{s}}a. Optimizer 220 then uses adjoint vectors λ_{J} and λ_{g} computed during step 908 to compute the gradient of objective function J with respect to aₗ as ∇ₐ_{ₗ}J using Equation 25. Optimizer 220 then computes the gradient of the objective function J with respect to the categorical design variable probabilities θⱼ as ∇_{θ}_{ⱼ}J using Equation 17. A similar approach is used to compute the gradient of constraint function(s) g is then computed similarly as ∇ₐ_{ₗ}g and the gradient of constraint function(s) g with respect to the categorical design variable probabilities θⱼ as ∇_{θ}_{ⱼ}g.

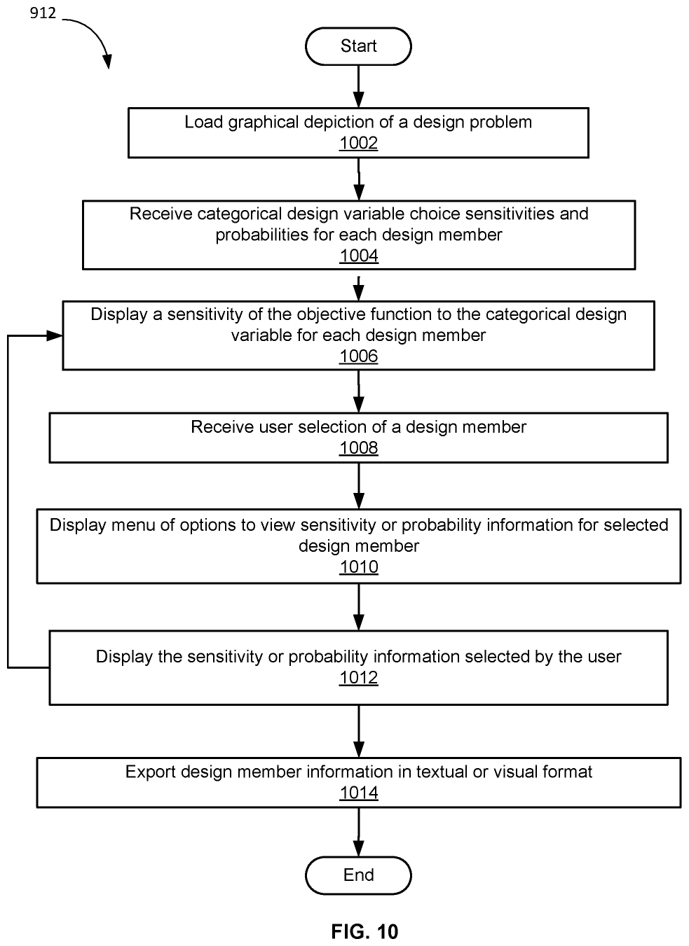

At step 914, visualizer 222 visualizes the impact of the categorical design variable choices on the objective function for the design problem. Visualizer 222 displays a user interface with a graphical depiction of the design problem rendering a color or intensity for each of the design members that corresponds to how sensitive the objective function for the design problem is to the choices for the categorical design variables. The user interface also gives the user options for learning more about the impact of the categorical design variable choices on the design problem and the objective function as described in further detail in FIG. 10.

At step 916, optimizer 220 updates the continuous design variables x and the categorical design variable probabilities θ using the gradients determined during step 912. Optimizer 220 uses the previous versions of the continuous design variables x along with the gradient of objective function J with respect to continuous design variables x as ∇ₓJ and the gradient of constraint function(s) g with respect to continuous design variables x as ∇ₓg determined during step 910 to update continuous design variables x. Optimizer 220 uses the previous versions of the categorical design variable probabilities θ along with the gradient of objective function J with respect to categorical design variable probabilities θⱼ as ∇_{θ}_{ⱼ}J and the gradient of constraint function(s) g with respect to categorical design variable probabilities θⱼ as ∇_{θ}_{ⱼ}g determined during step 912 to update categorical design variable probabilities θ.

At step 918, optimizer 220 determines whether the optimization is complete. Optimizer 220 uses a termination criterion to determine whether the optimization is complete. For example, if the values of the categorical and continuous design variables did not change more than a threshold amount over for a specific number of iterations of steps 906-916, optimizer determines that the termination criteria is met. If the termination criterion is not met, optimizer 220 returns to step 906 to perform an additional design iteration. If the termination criterion is met, optimizer 220 ends the optimization.

FIG. 10 sets forth a flow diagram of method steps for visualizing design a problem with categorical design variables, according to various embodiments. Although the method steps are described in conjunction with FIGS. 1-8, persons skilled in the art will understand that any system configured to perform the method steps, in any order, falls within the scope of the step 912 disclosure.

As shown, a step 912 begins at step 1002 where visualizer 222 loads a graphical depiction of the design problem. For example, when the design problem is a linear elasticity design problem, The design problem can be a frame structure as shown in 502. A design members of the design problem can have categorical and continuous variables.

At step 1004, visualizer 222 receives categorical design variable choice sensitivities and probabilities for each design member from optimizer 220. The categorical design variable choice sensitivities correspond to the gradients with respect to the categorical design probabilities θ determined by optimizer 220. For example, the optimizer can provide the categorical design variable choice sensitivities and probabilities after each design iteration.

At step 1006, visualizer 222 displays a sensitivity of the objective function to the categorical design variable choices for each design member 504. Visualizer 222 displays the sensitivity using a visual aspect used to display a respective design member 504. For example, the visual aspect could correspond to a color or intensity in which the respective design member 504 is displayed. For example, the sensitivity of the objective function to the categorical design variable choices for a design member 504 can be computed as an aggregation (e.g., a Euclidean norm) of the gradients of the objective function with respect to each categorical design variable choice for the design member 504. Visualizer 222 also display a key for interpreting the displayed visual aspects. For example, the key could be the color bar 506 used to indicate how the ranges of colors and/or intensities should be interpreted.

At step 1008, visualizer 222 receives from the user a selection design member 504 in graphical depiction 502. For example, the user can select a design member (e.g., 504(A) or 504(B)), by clicking on the design member 504, hovering the cursor over the design member 504, and/or the like.

At step 1010, visualizer 222 displays a menu of options to the user to view sensitivity or probability information for the selected design member. For example, visualizer 222 can show a pop-up menu with various options including tables, lists, pie charts, bar charts, stacked bar charts, and/or the like for displaying the probabilities of each categorical design choice appearing in a solution to the design problem or the sensitivity of the objective function to the categorical design variable choices.

At step 1012, after the user selects an option from the menu, visualizer 222 displays the sensitivity or probability information selected by the user. For example, the visualizer can add a pop-up window (e.g., pop-up windows 604, 704, or 804) to the user interface with the information selected by the user, such as by using any of the pop-up windows 604, 704, or 804. In addition, visualizer can also display a callout link (e.g., callout links 602, 702, or 802). Visualizer 222 can use the pop-up window to display the overall impact of each categorical design variable choice on the objective function or to display the likelihood of each categorical design variable choice being selected in the optimal solution for the design problem. The pop-up window can display sensitivities or probabilities using tables, lists, pie charts, bar charts, stacked bar charts, and/or the like. Although not shown, as the user makes additional selections of design members and/or information to be displayed, steps 1008, 1010, and 1012 can be repeated to replace a previously displayed pop-up window or to add additional pop-up windows.

At an optional step 1014, visualizer 222 allows the user to export the displayed design member information in a textual or visual format. For example, user can export the graphical depiction rendered colormaps corresponding to the impact on objective function or likelihood of each categorical design variable choice being selected in the optimal solution for the design problem as an image file, such as .PNG file, a .JPG file, and/or the like. Visualizer 222 can also export the sensitivity and/or probability information for the categorical design variable choices in various textual or graphic forms.

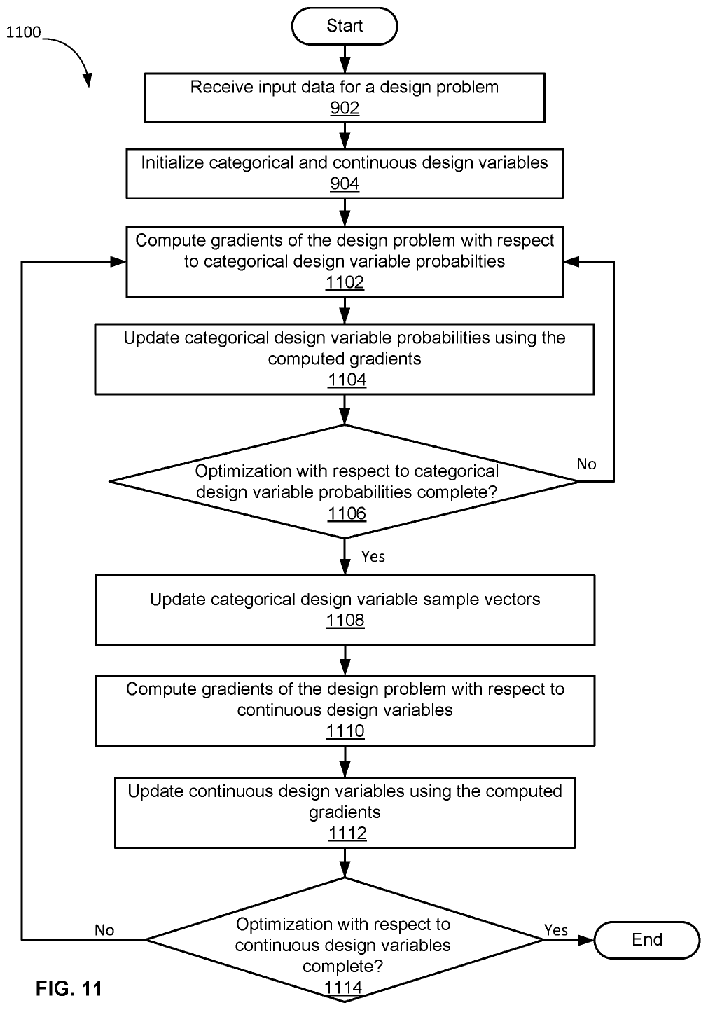

FIG. 11 sets forth a flow diagram of method steps for bi-level optimization of a design problem with categorical design variables, according to various embodiments. Although the method steps are described in conjunction with FIGS. 1-8, persons skilled in the art will understand that any system configured to perform the method steps, in any order, falls within the scope of the present disclosure.

As shown, a method 1100 begins at step 902 where optimizer 220 receives input data 218 for a design problem. For example, optimizer 220 receives an objective function J, one or more constraint functions g, continuous design variables x, bounds for the continuous design variables x, categorical variables c, available choices for the categorical variables c, and a temperature parameter τ for a simulated annealing process.

At step 904, optimizer 220 initializes continuous design variables x and categorical design variables c. Each continuous design variable x₁ is set to an initial value within the corresponding bounds for the design variable x₁, such as by selecting a random value within the bounds. Each available choice for each categorical design variable cᵢ is assigned an equal probability or alternatively a random probability.

At step 1102, optimizer 220 computes gradients of the design problem with respect to the categorical design variable probabilities. Optimizer 220 performs step 1102 using steps consistent with steps 906, 908, and 912.

At step 1104, optimizer 220 updates the categorical design variable probabilities θ using the computed gradients determined during step 1102. Optimizer 220 uses the previous versions of the categorical design variable probabilities θ along with the gradient of objective function J with respect to categorical design variable probabilities θⱼ as ∇_{θ}_{ⱼ}J and the gradient of constraint function(s) g with respect to categorical design variable probabilities θⱼ as ∇_{θ}_{ⱼ}g determined during step 1102 to update categorical design variable probabilities θ.

At step 1106, optimizer 220 determines whether optimization with respect to the categorical design variable probabilities is complete. Optimizer 220 uses a termination criterion to determine whether the optimization is complete. For example, if the values of the categorical design variables did not change more than a threshold amount over for a specific number of design iterations of steps 1102 and 1104, optimizer 220 determines that the termination criterion is met and optimizer 220 proceeds to step 1108 to update categorical design variable sample vectors. If the termination criterion is not met, optimizer 220 returns to step 1102 to repeat another iteration to further update the categorical design variable probabilities.

At step 1108, optimizer 220 updates the categorical design variable sample vectors. Optimizer 220 uses Equation 6 to update the soft one-hot sample vector s using the categorical design variable probabilities θ calculated during step 1106. Optimizer 220 then uses Equation 7 to update the true one-hot sample vector s.

At step 1110, optimizer 220 computes gradients of the design problem with respect to the continuous design variables. Optimizer 220 performs step 1110 using steps consistent with steps 908 and 910.

At step 1112, optimizer 220 updates continuous design variables using the computed gradients. Optimizer 220 updates the continuous design variables x using the gradients determined during step 1110. Optimizer 220 uses the previous versions of the continuous design variables x along with the gradient of objective function J with respect to continuous design variables x as ∇ₓJ and the gradient of constraint function(s) g with respect to continuous design variables x aa ∇ₓg determined during step 1110 to update continuous design variables x.

At step 1114, optimizer 220 determines whether optimization with respect to the continuous design variables is complete. Optimizer 220 uses a termination criterion to determine whether the optimization is complete. For example, if the values of the continuous design variables did not change more than a threshold amount over for a specific number of iterations of steps 1102-1114, optimizer determines that the termination criterion is met and optimizer 220 stops. If the termination criterion is not met, optimizer 220 returns to step 1102 to perform further design iterations.

Although not shown in FIG. 11, method 1100 can further include a step similar to step 914 for visualizing the impact of the categorical design choices on the objective function. For example, this visualization step could occur after step 1104 or between steps 1106 and 1114.

In sum, techniques for visualizing sensitivities and probabilities in a design problem involving categorical design variables are described. The techniques include receiving sensitivities and probabilities of the categorical design variable choices generated during an optimization process. The optimizer computes sensitivities of an objective function with respect to each categorical design variable choice for each design member of the design problem. The sensitivities are visualized by displaying a graphical depiction of the design members, where a visual aspect of each design member is determined based on the sensitivity of the objective function to the choices for the categorical design variables for that design member. A key for interpreting the visual aspects is also displayed.

In some embodiments, techniques for performing optimization on design problems involving mixed design variables include initializing values for the categorical design variable probabilities for the design problem and values for the continuous design variables for the design problem. Design iterations are then performed by generating sample vectors for each of the categorical design variables based on the categorical design variable probabilities. The governing equations for the design problem are solved and values for one or more constraint function(s) and an objective function of the design problem are computed. Gradients of the constraint function(s) and the objective function with respect to the continuous design variables and the categorical design variable probabilities are then computed and then used to update the values of the continuous design variables and the categorical design variable probabilities. The design iterations are repeated until a termination criteria for the optimization is met.

In some embodiments, the techniques include a bi-level optimization technique for performing optimization on design problems involving mixed design variables include initializing values for the categorical design variable probabilities for the design problem and values for the continuous design variables for the design problem. Design iterations are then performed by performing one or more iterations to update the categorical design variable probabilities. Each iteration to update the categorical design variable probabilities includes generating sample vectors for each of the categorical design variables based on the categorical design variable probabilities, computing gradients of one or more constraint functions and an objective function with respect to the categorical design variable probabilities, and then updating the values of the categorical design variable probabilities. After the one or more iterations to update the categorical design variable probabilities are complete, the sample vectors are updated based on the updated categorical design variable probabilities. Gradients of the constraint function(s) and the objection function are computed with respect to the continuous design variable and then used to update values for the continuous design variables. The design iterations are repeated until a termination criteria for the optimization is met.

At least one technical advantage of the disclosed techniques relative to the prior art is that, with the disclosed techniques, gradient-based optimization techniques to be used for design problems with both continuous design variables and categorical design variables. The disclosed techniques further provide improved ways to view the impact and relevance of different categorical design variable choices on a design problem. The disclosed techniques enable the user to quickly compare different choices for the same categorical design variable and the impact of those choices on a design solution without having to compare and contrast many different design solutions to infer the impact of the choices. As a result, the overall design process can be completed faster. In addition, the disclosed techniques are more computationally efficient than prior art techniques and use fewer computing resources. These technical advantages provide one or more technological improvements over prior art approaches.

1. In some embodiments, a computer-implemented method for evaluating an impact of categorical design variables on a design problem solution comprises receiving information regarding choices for one or more categorical design variables associated with each of a plurality of design members of a design problem, determining a respective sensitivity of an objective function to the choices for the one or more categorical design variables for each design member of the plurality of design members, determining a respective visual aspect for each design member based on the respective sensitivity, displaying, on a user interface, a graphical depiction of the plurality of design members, wherein each design member is displayed using the respective visual aspect, and displaying, on the user interface, a key for interpreting the respective visual aspects.

2. The computer-implemented method of clause 1, wherein the respective visual aspect for a first design member is a color in which the first design member is displayed.

3. The computer-implemented method of clauses 1 or 2, wherein the respective visual aspect for a first design member is an intensity in which the first design member is displayed.

4. The computer-implemented method of any of clauses 1-3, wherein determining the respective sensitivity for a first design member comprises computing an aggregation of a gradient of the objective function with respect to each of the choices for the one or more categorical design variables.

5. The computer-implemented method of any of clauses 1-4, further comprising receiving, from a user, a selection of a first design member of the plurality of design members, and displaying, on the user interface, options for viewing the information regarding the choices for the one or more categorical design variables for the first design member.

6. The computer-implemented method of any of clauses 1-5, wherein the user makes the selection by clicking on the first design member or hovering a cursor over the first design member.

7. The computer-implemented method of any of clauses 1-6, wherein the options include one or more of viewing an impact of each of the choices for a first categorical design variable of the one or more categorical design variables on the objective function or a likelihood each of the choices for the first categorical design variable are chosen for a solution to the design problem.

8. The computer-implemented method of any of clauses 1-7, wherein the options include one or more of viewing the information using a table, a list, a pie chart, a bar chart, or a stacked bar chart.

9. The computer-implemented method of any of clauses 1-8, wherein the options for viewing the information are displayed in a pop-up menu.

10. The computer-implemented method of any of clauses 1-9, further comprising receiving, from the user, a selection of a first option of the options, and displaying, on the user interface in a pop-up window, the information based on the first option.

11. The computer-implemented method of any of clauses 1-10, further comprising displaying a callout link between the first design member and the pop-up window.

12. The computer-implemented method of any of clauses 1-11, wherein the pop-up window includes one or more of a design member label, a table, a list, a pie chart, a bar chart, a stacked bar chart, or a list of the choices for a first categorical design variable of the one or more categorical design variables.

13. The computer-implemented method of any of clauses 1-12, wherein each design member corresponds to a truss element in a physical structure.

14. In some embodiments, one or more non-transitory computer readable media store instructions that, when executed by one or more processors, cause the one or more processors to perform the steps of receiving information regarding choices for one or more categorical design variables associated with each of a plurality of design members of a design problem, determining a respective sensitivity of an objective function to the choices for the one or more categorical design variables for each design member of the plurality of design members, determining a respective visual aspect for each design member based on the respective sensitivity, displaying, on a user interface, a graphical depiction of the plurality of design members, wherein each design member is displayed using the respective visual aspect, and displaying, on the user interface, a key for interpreting the respective visual aspects.

15. The one or more non-transitory computer-readable media of clause 14, wherein the respective visual aspect for a first design member is a color or an intensity in which the first design member is displayed.

16. The one or more non-transitory computer-readable media of clauses 14 or 15, wherein determining the respective sensitivity for a first design member comprises computing an aggregation of a gradient of the objective function with respect to each of the choices for the one or more categorical design variables.

17. The one or more non-transitory computer-readable media of any of clauses 14-16, wherein the steps further comprise receiving, from a user, a selection of a first design member of the plurality of design members, and displaying, on the user interface, options for viewing the information regarding the choices for the one or more categorical design variables for the first design member.

18. The one or more non-transitory computer-readable media of any of clauses 14-17, wherein the steps further comprise receiving, from the user, a selection of a first option of the options, and displaying, on the user interface in a pop-up window, the information based on the first option.

19. The one or more non-transitory computer-readable media of any of clauses 14-18, wherein the steps further comprise displaying a callout link between the first design member and the pop-up window.

20. In some embodiments, a system comprises one or more memories storing instructions, and one or more processors that are coupled to the one or more memories and, when executing the instructions, are configured to receive information regarding choices for one or more categorical design variables associated with each of a plurality of design members of a design problem, determine a respective sensitivity of an objective function to the choices for the one or more categorical design variables for each design member of the plurality of design members, determine a respective visual aspect for each design member based on the respective sensitivity, display, on a user interface, a graphical depiction of the plurality of design members, wherein each design member is displayed using the respective visual aspect, and display, on the user interface, a key for interpreting the respective visual aspects.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for evaluating an impact of categorical design variables on a design problem solution, the method comprising:
receiving information regarding choices for one or more categorical design variables associated with each of a plurality of design members of a design problem;
determining a respective sensitivity of an objective function to the choices for the one or more categorical design variables for each design member of the plurality of design members;
determining a respective visual aspect for each design member based on the respective sensitivity;
displaying, on a user interface, a graphical depiction of the plurality of design members, wherein each design member is displayed using the respective visual aspect; and
displaying, on the user interface, a key for interpreting the respective visual aspects.

2. The computer-implemented method of claim 1, wherein the respective visual aspect for a first design member is a color in which the first design member is displayed.

3. The computer-implemented method of claim 1, wherein the respective visual aspect for a first design member is an intensity in which the first design member is displayed.

4. The computer-implemented method of claim 1, wherein determining the respective sensitivity for a first design member comprises computing an aggregation of a gradient of the objective function with respect to each of the choices for the one or more categorical design variables.

5. The computer-implemented method of claim 1, further comprising:
receiving, from a user, a selection of a first design member of the plurality of design members; and
displaying, on the user interface, options for viewing the information regarding the choices for the one or more categorical design variables for the first design member.

6. The computer-implemented method of claim 5, wherein the user makes the selection by clicking on the first design member or hovering a cursor over the first design member.

7. The computer-implemented method of claim 5, wherein the options include one or more of viewing an impact of each of the choices for a first categorical design variable of the one or more categorical design variables on the objective function or a likelihood each of the choices for the first categorical design variable are chosen for a solution to the design problem.

8. The computer-implemented method of claim 5, wherein the options include one or more of viewing the information using a table, a list, a pie chart, a bar chart, or a stacked bar chart.

9. The computer-implemented method of claim 5, wherein the options for viewing the information are displayed in a pop-up menu.

10. The computer-implemented method of claim 5, further comprising:
receiving, from the user, a selection of a first option of the options; and
displaying, on the user interface in a pop-up window, the information based on the first option.

11. The computer-implemented method of claim 10, further comprising displaying a callout link between the first design member and the pop-up window.

12. The computer-implemented method of claim 10, wherein the pop-up window includes one or more of a design member label, a table, a list, a pie chart, a bar chart, a stacked bar chart, or a list of the choices for a first categorical design variable of the one or more categorical design variables.

13. The computer-implemented method of claim 1, wherein each design member corresponds to a truss element in a physical structure.

14. One or more non-transitory computer readable media storing instructions that, when executed by one or more processors, cause the one or more processors to perform the steps of:
receiving information regarding choices for one or more categorical design variables associated with each of a plurality of design members of a design problem;
determining a respective sensitivity of an objective function to the choices for the one or more categorical design variables for each design member of the plurality of design members;
determining a respective visual aspect for each design member based on the respective sensitivity;
displaying, on a user interface, a graphical depiction of the plurality of design members, wherein each design member is displayed using the respective visual aspect; and
displaying, on the user interface, a key for interpreting the respective visual aspects.

15. The one or more non-transitory computer-readable media of claim 14, wherein the respective visual aspect for a first design member is a color or an intensity in which the first design member is displayed.

16. The one or more non-transitory computer-readable media of claim 14, wherein determining the respective sensitivity for a first design member comprises computing an aggregation of a gradient of the objective function with respect to each of the choices for the one or more categorical design variables.

17. The one or more non-transitory computer-readable media of claim 14, wherein the steps further comprise:
receiving, from a user, a selection of a first design member of the plurality of design members; and
displaying, on the user interface, options for viewing the information regarding the choices for the one or more categorical design variables for the first design member.

18. The one or more non-transitory computer-readable media of claim 17, wherein the steps further comprise:
receiving, from the user, a selection of a first option of the options; and
displaying, on the user interface in a pop-up window, the information based on the first option.

19. The one or more non-transitory computer-readable media of claim 18, wherein the steps further comprise displaying a callout link between the first design member and the pop-up window.

20. A system comprising:
one or more memories storing instructions, and
one or more processors that are coupled to the one or more memories and, when executing the instructions, are configured to:
receive information regarding choices for one or more categorical design variables associated with each of a plurality of design members of a design problem;
determine a respective sensitivity of an objective function to the choices for the one or more categorical design variables for each design member of the plurality of design members;
determine a respective visual aspect for each design member based on the respective sensitivity;
display, on a user interface, a graphical depiction of the plurality of design members, wherein each design member is displayed using the respective visual aspect; and
display, on the user interface, a key for interpreting the respective visual aspects.
